(19) United States
(12) Patent Application Publication
(10) Pub. No.: US 2026/0025118 A1
(43) Pub. Date: Jan. 22, 2026

(54) FILTER DEVICE AND RADIO-FREQUENCY FRONT-END CIRCUIT

(71) Applicant: Murata Manufacturing Co., Ltd., Nagaokakyo-shi (JP)

(72) Inventor: Ryouta NOBE, Nagaokakyo-shi (JP)

(21) Appl. No.: 19/211,508

(22) Filed: May 19, 2025

(30) Foreign Application Priority Data
Jul. 16, 2024 (JP) 2024-113438

(51) Int. Cl. H03H 7/01; H03H 1/00

(52) U.S. Cl. CPC H03H 7/0115; H03H 1/00; H03H 2001/0085

(57) ABSTRACT

A filter device includes a dielectric substrate, first and second terminals on an outer surface of the dielectric substrate, first and second resonant circuits, and first and second ground electrodes. The first resonant circuit is connected to the first terminal. The second resonant circuit is connected to the second terminal. The first ground electrode is connected to the first resonant circuit. The second ground electrode is connected to the second resonant circuit and is separated from the first ground electrode.

### CROSS REFERENCE TO RELATED APPLICATIONS

This application claims the benefit of priority to Japanese Patent Application No. 2024-113438 filed on Jul. 16, 2024. The entire contents of this application are hereby incorporated herein by reference.

### BACKGROUND OF THE INVENTION

### 1. Field of the Invention

The present disclosure relates to filter devices and radio-frequency front-end circuits including the filter devices and more specifically, relates to technologies to improve filter characteristics of filter devices including multiple LC resonant circuits.

### 2. Description of the Related Art

International Publication No. 2022/071191 discloses a filter device including multiple LC resonant circuits that are disposed in a dielectric substrate formed by laminating multiple dielectric layers. In the filter device disclosed in International Publication No. 2022/071191, some of the resonant circuits are connected to a ground terminal through paths including a common part.

### SUMMARY OF THE INVENTION

Such a filter device including multiple resonant circuits often has a configuration in which the resonant circuits are connected to a common ground electrode. With this configuration, because a common ground electrode is used, it is possible to reduce the variation in the ground potential among the resonant circuits and thereby stabilize the ground potential.

On the other hand, because current distribution occurs even in a ground electrode, when a common ground electrode is used, an electric current may flow between the resonant circuits via the ground electrode, and as a result, strong magnetic coupling may occur between the resonant circuits. When magnetic coupling unintended in the design stage occurs between the resonant circuits, it becomes difficult to achieve desired filter characteristics.

Example embodiments of the present invention reduce the degradation of filter characteristics of filter devices including multiple resonant circuits.

A filter device according to an example embodiment of the present disclosure includes a dielectric substrate, a first terminal and a second terminal on an outer surface of the dielectric substrate, a first resonant circuit, a second resonant circuit, a first ground electrode, and a second ground electrode. The first resonant circuit is connected to the first terminal. The second resonant circuit is connected to the second terminal. The first ground electrode is connected to the first resonant circuit. The second ground electrode is connected to the second resonant circuit and is separated from the first ground electrode.

In a filter device according to an example embodiment of the present disclosure, the ground electrodes connected to the two resonant circuits are separated from each other. This makes it possible to prevent an electric current from flowing between the resonant circuits via a ground electrode and thus makes it possible to prevent unintended magnetic coupling between the resonant circuits. Accordingly, in a filter device including multiple resonant circuits, the above configuration makes it possible to prevent the degradation of filter characteristics resulting from unintended magnetic coupling between the resonant circuits.

The above and other elements, features, steps, characteristics and advantages of the present invention will become more apparent from the following detailed description of the example embodiments with reference to the attached drawings.

### BRIEF DESCRIPTION OF THE DRAWINGS

FIG. 1 is a block diagram of a communication apparatus including a radio-frequency front-end circuit for which a filter device according to a first example embodiment of the present invention is used.

FIG. 2 is an equivalent circuit diagram of the filter device according to the first example embodiment of the present invention.

FIG. 3 is an external perspective view of the filter device according to the first example embodiment of the present invention.

FIG. 4 is an exploded perspective view of an example of a multilayer structure of the filter device illustrated in FIG. 3.

FIG. 5 is an exploded perspective view of a multilayer structure of a filter device according to a comparative example.

FIG. 6 is a graph for describing filter characteristics of the filter devices according to the first example embodiment of the present invention and the comparative example.

FIG. 7 is an equivalent circuit diagram of a filter device according to a first variation of an example embodiment of the present invention.

FIG. 8 is an exploded perspective view of an example of a multilayer structure of the filter device according to the first variation of an example embodiment of the present invention.

FIG. 9 is an equivalent circuit diagram of a filter device according to a second example embodiment of the present invention.

FIG. 10 is an external perspective view of the filter device according to the second example embodiment of the present invention.

FIG. 11 is an exploded perspective view of an example of a multilayer structure of the filter device illustrated in FIG. 10.

FIG. 12 is an equivalent circuit diagram of a filter device according to a second variation of an example embodiment of the present invention.

FIG. 13 is an exploded perspective view of an example of a multilayer structure of the filter device according to the second variation of an example embodiment of the present invention.

FIG. 14 is an equivalent circuit diagram of a filter device according to a third variation of an example embodiment of the present invention.

FIG. 15 is an exploded perspective view of an example of a multilayer structure of the filter device according to the third variation of an example embodiment of the present invention.

### DETAILED DESCRIPTION OF THE EXAMPLE EMBODIMENTS

Example embodiments of the present disclosure are described in detail below with reference to the drawings. The same reference number is assigned to the same or similar components in the drawings, and the descriptions of those components are not repeated.

### First Example Embodiment

### Basic Configuration of Communication Apparatus

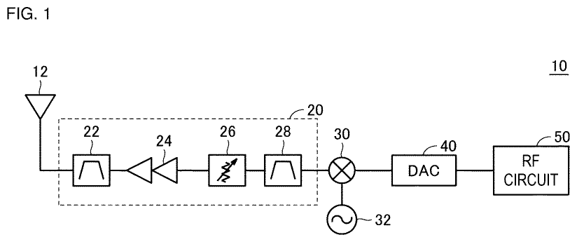

FIG. 1 is a block diagram of a communication apparatus 10 including a radio-frequency front-end circuit 20 for which a filter device according to an example embodiment is usable. The communication apparatus 10 is, for example, a mobile terminal, such as a smartphone, or a mobile phone base station.

Referring to FIG. 1, the communication apparatus 10 includes an antenna 12, a radio-frequency front-end circuit 20, a mixer 30, a local oscillator 32, a D/A converter (DAC) 40, and an RF circuit 50. Also, the radio-frequency front-end circuit 20 includes band pass filters 22 and 28, an amplifier 24, and an attenuator 26. In FIG. 1, it is assumed that the radio-frequency front-end circuit 20 includes a transmitter circuit that transmits a radio frequency signal from the antenna 12. However, the radio-frequency front-end circuit 20 may include a receiver circuit that receives a radio frequency signal via the antenna 12.

The communication apparatus 10 up-converts a transmission signal received from the RF circuit 50 into a radio frequency signal and transmits the radio frequency signal from the antenna 12. A modulated digital signal, which is a transmission signal output from the RF circuit 50, is converted to an analog signal by the D/A converter 40. The mixer 30 mixes the transmission signal, which has been converted from a digital signal to an analog signal by the D/A converter 40, with an oscillation signal from the local oscillator 32 and thus up-converts the transmission signal into a radio frequency signal. The band pass filter 28 removes spurious waves generated by the up-conversion and thus extracts only a transmission signal in a desired frequency band. The attenuator 26 adjusts the intensity of the transmission signal. The amplifier 24 amplifies the power of the transmission signal passed through the attenuator 26 to a predetermined level. The band pass filter 22 removes spurious waves generated in the amplification process and thus transmits only a signal component in a frequency band specified by a communication standard. The transmission signal passed through the band pass filter 22 is transmitted from the antenna 12.

A filter device according to an example embodiment of the present disclosure may be used as each of the band pass filters 22 and 28 of the communication apparatus 10 described above.

### Configuration of Filter Device

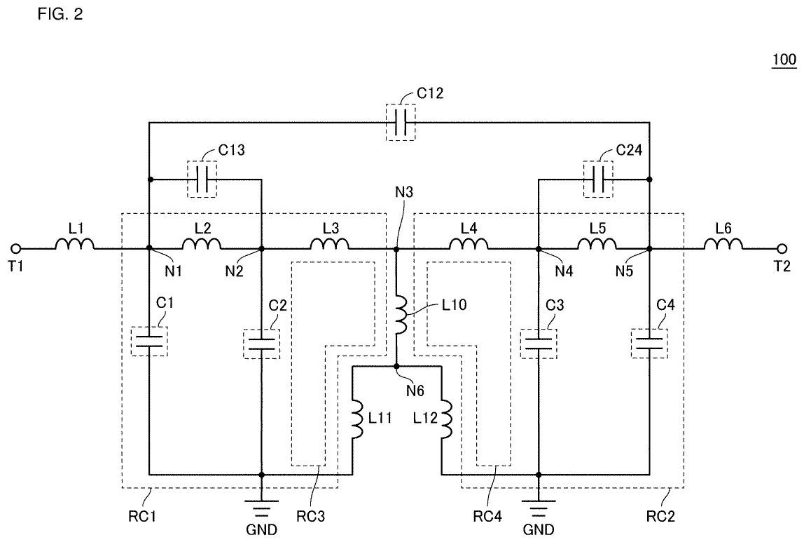

Next, a detailed configuration of a filter device 100 of a first example embodiment is described with reference to FIGS. 2 to 4.

### (1) Equivalent Circuit

FIG. 2 is an equivalent circuit diagram of the filter device 100. Referring to FIG. 2, the filter device 100 includes an input terminal T1, an output terminal T2, and resonant circuits RC1 to RC4. Each of the resonant circuits RC1 to RC4 is an LC parallel resonant circuit in which one or more inductors are connected in parallel with one or more capacitors.

The resonant circuit RC1 is connected to the input terminal T1 via an inductor L1. The resonant circuit RC1 includes inductors L2, L3, L10, and L11 and a capacitor C1. The inductors L2, L3, L10, and L11 are connected in series, in this order, between a connection node N1, which is connected to the inductor L1, and a ground terminal GND. The capacitor C1 is also connected between the connection node N1 and the ground terminal GND. That is, the resonant circuit RC1 is an LC parallel resonant circuit in which a composite inductor consisting of the series-connected inductors L2, L3, L10, and L11 is connected in parallel with the capacitor C1.

The resonant circuit RC2 is connected to the output terminal T2 via an inductor L6. The resonant circuit RC2 includes inductors L4, L5, L10, and L12 and a capacitor C4. The inductors L5, L4, L10, and L12 are connected in series, in this order, between a connection node N5, which is connected to the inductor L6, and a ground terminal GND. The capacitor C4 is also connected between the connection node N5 and the ground terminal GND. That is, the resonant circuit RC2 is an LC parallel resonant circuit in which a composite inductor consisting of the series-connected inductors L4, L5, L10, and L12 is connected in parallel with the capacitor C2.

The resonant circuit RC3 includes the inductors L3, L10, and L11 and a capacitor C2. The capacitor C2 is connected between the ground terminal GND and a connection node N2 between the inductors L2 and L3. The inductors L3, L10, and L11 are portions of the inductors defining the resonant circuit RC1 and are connected in series between the connection node N2 and the ground terminal GND. That is, the resonant circuit RC3 is an LC parallel resonant circuit in which a composite inductor including the series-connected inductors L3, L10, and L11 is connected in parallel with the capacitor C2.

The resonant circuit RC4 includes the inductors L4, L10, and L12 and a capacitor C3. The capacitor C3 is connected between the ground terminal GND and a connection node N3 between the inductors L4 and L5. The inductors L4, L10, and L12 are portions of the inductors defining the resonant circuit RC2 and are connected in series between a connection node N4 and the ground terminal GND. That is, the resonant circuit RC4 is an LC parallel resonant circuit in which a composite inductor including the series-connected inductors L4, L10, and L12 is connected in parallel with the capacitor C3.

As described above, the inductors L3, L10, and L11 are shared by the resonant circuits RC1 and RC3. Therefore, the resonant circuits RC1 and RC3 are magnetically coupled with each other. Also, the inductors L4, L10, and L12 are shared by the resonant circuits RC2 and RC4. Therefore, the resonant circuits RC2 and RC4 are magnetically coupled with each other.

The inductor L10 is connected between the connection node N3, which is between the inductors L3 and L4, and a connection node N6, which is between the inductors L11 and L12, and is shared by the resonant circuits RC1 to RC4. Therefore, the resonant circuits RC1 to RC4 are magnetically coupled with each other by the inductor L10.

A capacitor C13 is connected in parallel with the inductor L2. With this configuration, the resonant circuits RC1 and RC3 are capacitively coupled with each other. Also, a capacitor C24 is connected in parallel with the inductor L5. With this configuration, the resonant circuits RC2 and RC4 are capacitively coupled with each other. Furthermore, a capacitor C12 is connected between the connection node N1 and the connection node N5. With this configuration, the resonant circuits RC1 and RC2 are capacitively coupled with each other.

Thus, the filter device 100 has a configuration in which four stages of resonant circuits, which are magnetically and capacitively coupled with each other, are provided in a signal transmission path between the input terminal T1 and the output terminal T2. By adjusting the resonant frequencies of the resonators, the filter device 100 functions as a band pass filter that passes a signal in a desired frequency band. The number of resonant circuits included in a filter device is not limited to the above example, and the present disclosure is applicable to any filter device that includes two or more resonators.

### (2) Structural Detail

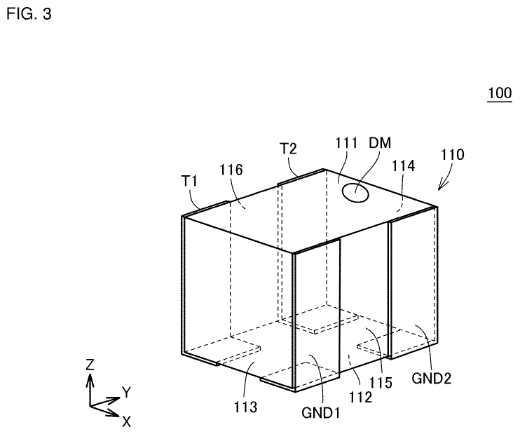

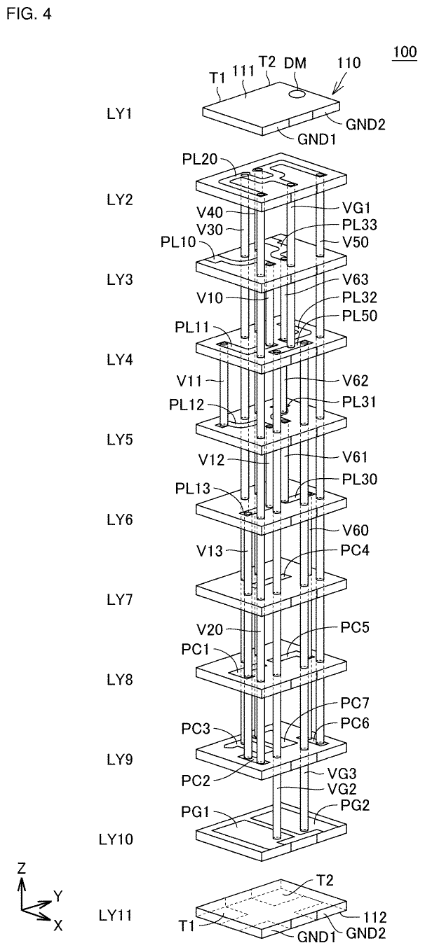

Next, an example of a structure of the filter device 100 is described with reference to FIGS. 3 and 4. FIG. 3 is an external perspective view of the filter device 100, and FIG. 4 is an exploded perspective view of an example of a multilayer structure of the filter device 100.

Referring to FIGS. 3 and 4, the filter device 100 includes a dielectric substrate 110 that has a cuboid or substantially cuboid shape and is formed by laminating multiple dielectric layers LY1 to LY11 in a laminating direction. Each of the dielectric layers LY1 to LY11 is formed of a ceramic, such as a low temperature co-fired ceramic (LTCC), or a resin. Inside of the dielectric substrate 110, multiple electrodes on or in the dielectric layers and multiple vias provided between the dielectric layers constitute inductors and capacitors of LC parallel resonant circuits. In the present application, “via” refers to a conductor that is provided in dielectric layers to connect electrodes on or in different dielectric layers. For example, a via is formed of a conductive paste, plating, and/or a metal pin.

In the descriptions below, “Z-axis direction” corresponds to the laminating direction of the dielectric layers LY1 to LY11 of the dielectric substrate 110; “X-axis direction” indicates a direction that is perpendicular to the Z-axis direction” and extends along one side of the dielectric substrate 110; and “Y-axis direction” indicates a direction that is perpendicular to the Z-axis direction” and extends along another side of the dielectric substrate 110. Also, in the descriptions below, the positive Z-axis direction and the negative Z-axis direction in each drawing may be referred to as “upper” and “lower”, respectively.

A directional mark DM to identify the orientation of the filter device 100 is on an upper surface 111 (or the dielectric layer LY1) of the dielectric substrate 110. Ground terminals GND1 and GND2 extend from a side surface 115 of the dielectric substrate 110 facing the positive X-axis direction to a lower surface 112 (or the dielectric layer LY11) of the dielectric substrate 110. The ground terminal GND1 is located on the side surface 115 at a position closer to a side surface 113 facing the negative Y-axis direction. The ground terminal GND2 is located on the side surface 115 at a position closer to a side surface 114 facing the positive Y-axis direction.

Also, the input terminal T1 and the output terminal T2 extend from a side surface 116 of the dielectric substrate 110 facing the negative X-axis direction to the lower surface 112. The input terminal T1 is located on the side surface 115 at a position closer to the side surface 113. The output terminal T2 is located on the side surface 115 at a position closer to the side surface 114.

Each of the input terminal T1, the output terminal T2, the ground terminal GND1, and the ground terminal GND2 has a substantially L-shape formed by bending a portion of a planar electrode. The input terminal T1, the output terminal T2, and the ground terminals GND1 and GND2 are used as external terminals for connection with external devices.

The input terminal T1 is connected, on the side surface 116, to a planar electrode PL10 on or in the dielectric layer LY3. The planar electrode PL10 is a strip electrode having an arc shape. A first end of the planar electrode PL10 is connected to the input terminal T1. A second end of the planar electrode PL10 is connected through a via V10 to a planar electrode PL11 on or in the dielectric layer LY4.

The planar electrode PL11 is a strip electrode having a substantially L-shape. A first end of the planar electrode PL11 is connected to the via V10. A second end of the planar electrode PL11 is connected through a via V11 to a planar electrode PL12 on or in the dielectric layer LY5.

Similarly to the planar electrode PL10, the planar electrode PL12 is a strip electrode having an arc shape. A first end of the planar electrode PL12 is connected to the via V11. A second end of the planar electrode PL12 is connected through a via V12 to a planar electrode PL13 on or in the dielectric layer LY6.

The planar electrode PL13 is a linear electrode extending in the Y-axis direction. A first end of the planar electrode PL13 is connected to the via V12. A second end of the planar electrode PL13 is connected through a via V13 to a capacitor electrode PC1 on or in the dielectric layer LY8 and a capacitor electrode PC2 on or in the dielectric layer LY9.

The inductor L1 in FIG. 2 includes the planar electrodes PL10, PL11, PL12, and PL13 and the vias V10, V11, V12, and V13.

The capacitor electrode PC2 is a linear electrode extending in the X-axis direction. In plan view from the normal direction of the dielectric substrate 110, the capacitor electrode PC2 at least partially overlaps a ground electrode PG1 on or in the dielectric layer LY10. The ground electrode PG1 is a planar electrode having a substantially rectangular shape and is connected to the ground terminal GND1 on the side surface 115 of the dielectric substrate 110. The capacitor C1 in FIG. 2 includes the capacitor electrode PC2 and the ground terminal GND1.

Also, the capacitor electrode PC2 is connected through a via V20 to a planar electrode PL20 on or in the dielectric layer LY2. The planar electrode PL20 has a substantially M-shape. In addition to the via V20, vias V30, V40, V50, and VG1 are connected to the planar electrode PL20. The via V20 is connected to a first end of the planar electrode PL20, and the via V50 is connected to a second end of the planar electrode PL20. The vias V30, VG1, and V40 are connected in this order to the planar electrode PL20 along the path from the first end to the second end. “Planar electrode PL20” in the first example embodiment corresponds to “common electrode” in the present disclosure.

The via V30 is connected to the planar electrode PL20 and a capacitor electrode PC3 on or in the dielectric layer LY9. The capacitor electrode PC3 is a planar electrode having a substantially L-shape and is spaced apart from the capacitor electrode PC2. In plan view from the normal direction of the dielectric substrate 110, at least a portion of the capacitor electrode PC3 overlaps the ground electrode PG1 on or in the dielectric layer LY10.

The inductor L2 in FIG. 2 includes the vias V20 and V30 and a path of the planar electrode PL20 from the via V20 to the via V30. Also, the capacitor C2 in FIG. 2 includes the capacitor electrode PC3 and the ground electrode PG1.

The capacitor electrode PC1 connected, on or in the dielectric layer LY8, to the via V13 is a planar electrode having a substantially L-shape. In plan view from the normal direction of the dielectric substrate 110, at least a portion of the capacitor electrode PC1 overlaps the capacitor electrode PC3. The capacitor C13 in FIG. 2 includes the capacitor electrodes PC1 and PC3.

The via VG1 is connected to the planar electrode PL20 at an intermediate position along the path from the first end to the second end of the planar electrode PL20. The inductor L3 in FIG. 2 includes a path of the planar electrode PL20 from the via V30 to the via VG1. Also, the inductor L4 in FIG. 2 includes a path of the planar electrode PL20 from the via V40 to the via VG1. The via VG1 is connected to a planar electrode PL50 on or in the dielectric layer LY4.

The planar electrode PL50 is a linear electrode extending in the Y-axis direction, and the via VG1 is connected to an intermediate portion of the planer electrode PL50. A first end of the planar electrode PL50 is connected through a via VG2 to the ground electrode PG1 on or in the dielectric layer LY10. A second end of the planar electrode PL50 is connected through a via VG3 to the ground electrode PG2 on or in the dielectric layer LY10.

The ground electrode PG2 is a planar electrode that is symmetrical to the ground electrode PG1 and is spaced apart from the ground electrode PG1 in the positive Y-axis direction. The ground electrode PG2 is connected to the ground terminal GND2 on the side surface 115 of the dielectric substrate 110.

The inductor L10 in FIG. 2 includes the via VG1. Also, the inductor L11 and the inductor L12 in FIG. 2 are implemented by the via VG2 and the via VG3, respectively.

The via V40 is connected to the planar electrode PL20 and a capacitor electrode PC7 on or in the dielectric layer LY9. The capacitor electrode PC7 is a planar electrode having a substantially L-shape that is symmetrical to a capacitor electrode PC3. The capacitor electrode PC7 is spaced apart from the capacitor electrode PC3. In plan view from the normal direction of the dielectric substrate 110, at least a portion of the capacitor electrode PC7 overlaps the ground electrode PG2 on or in the dielectric layer LY10. The capacitor C3 in FIG. 2 includes the capacitor electrode PC7 and the ground electrode PG2.

The via V50 connected to the second end of the planar electrode PL20 is connected to a capacitor electrode PC6 on or in the dielectric layer LY9. Similarly to the capacitor electrode PC2, the capacitor electrode PC6 is a planar electrode having a linear shape and extending in the X-axis direction and is spaced apart from the capacitor electrode PC7. In plan view from the normal direction of the dielectric substrate 110, at least a portion of the capacitor electrode PC6 overlaps the ground electrode PG2 on or in the dielectric layer LY10.

The inductor L5 in FIG. 2 includes the vias V40 and V50 and a path of the planar electrode PL20 from the via V40 to the via V50. Also, the capacitor C4 in FIG. 2 includes the capacitor electrode PC6 and the ground electrode PG2.

The capacitor electrode PC6 is connected through a via V60 to a capacitor electrode PC5 on or in the dielectric layer LY8 and a planar electrode PL30 on or in the dielectric layer LY6.

The capacitor electrode PC5 is a planar electrode having a substantially L-shape that is symmetrical to the capacitor electrode PC1. In plan view from the normal direction of the dielectric substrate 110, a portion of the capacitor electrode PC5 overlaps the capacitor electrode PC7 on or in the dielectric layer LY9. The capacitor C24 in FIG. 2 includes the capacitor electrode PC5 and the capacitor electrode PC7.

Also, in plan view from the normal direction of the dielectric substrate 110, both of the capacitor electrode PC1 and the capacitor electrode PC5 on or in the dielectric layer LY8 partially overlap the capacitor electrode PC4 on or in the dielectric layer LY7. The capacitor C12 in FIG. 2 includes the capacitor electrode PC1, the capacitor electrode PC4, and the capacitor electrode PC5.

The planar electrode PL30 is a linear electrode extending in the Y-axis direction, and the via V30 is connected to a first end of the planar electrode PL30. A second end of the planar electrode PL30 is connected through a via V61 to a planar electrode PL31 on or in the dielectric layer LY5.

The planar electrode PL31 has an arc shape that is symmetrical to the planar electrode PL12, and the via V61 is connected to a first end of the planar electrode PL31. A second end of the planar electrode PL31 is connected through a via V62 to a planar electrode PL32 on or in the dielectric layer LY4.

The planar electrode PL32 has a substantially L-shape that is symmetrical to the planar electrode PL11, and the via V62 is connected to a first end of the planar electrode PL32. A second end of the planar electrode PL32 is connected through a via V63 to a planar electrode PL33 on or in the dielectric layer LY3.

The planar electrode PL33 has an arc shape that is symmetrical to the planar electrode PL10, and the via V63 is connected to a first end of the planar electrode PL33. A second end of the planar electrode PL33 is connected to the output terminal T2 on the side surface 116.

The inductor L6 in FIG. 2 includes the vias V60, V61, V62, and V63 and the planar electrodes PL30, PL31, PL32, and PL33.

### (3) Filter Characteristics

In a filter device including multiple resonant circuits as described above, the resonant circuits are typically connected to a common ground electrode. With such a configuration, because a common ground electrode is used, it is possible to reduce the variation in the ground potential among the resonant circuits and thereby stabilize the ground potential.

On the other hand, when a common ground electrode is used, a current may flow between the resonant circuits via the ground electrode, and as a result, strong magnetic coupling may occur between the resonant circuits. When magnetic coupling unintended in the design stage occurs between the resonant circuits, it becomes difficult to achieve desired filter characteristics. Such magnetic coupling may be prevented by increasing the distance between vias. However, this results in an increase in the size of the filter device and makes it difficult to reduce the size of the filter device.

Therefore, in the filter device 100 of the first example embodiment, a ground electrode connected to some resonant circuits is spaced apart from a ground electrode connected to other resonant circuits. Specifically, the ground electrode PG1 connected to the resonant circuits RC1 and RC3 is spaced apart from the ground electrode PG2 connected to the resonant circuits RC2 and RC4. This configuration prevents the flow of an electric current between the ground electrode PG1 and the ground electrode PG2 and thus makes it possible to prevent the magnetic coupling between the resonant circuits RC1 and RC3 and the resonant circuits RC2 and RC4, which results from an electric current flowing through the ground electrodes, while reducing the overall size of the filter device.

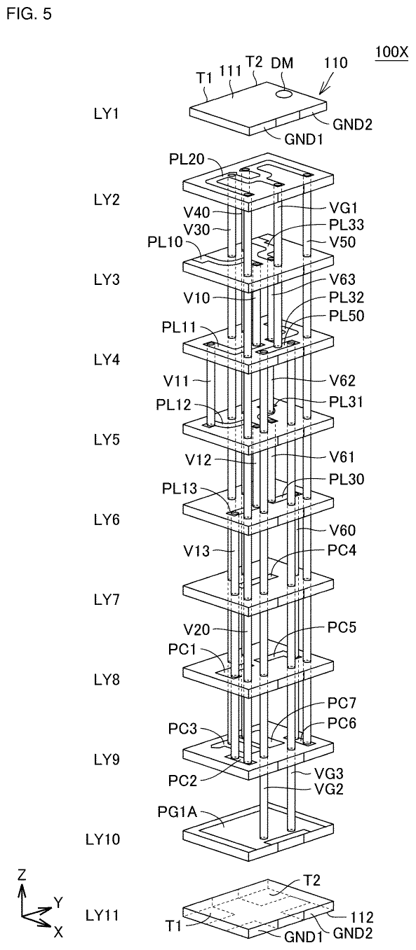

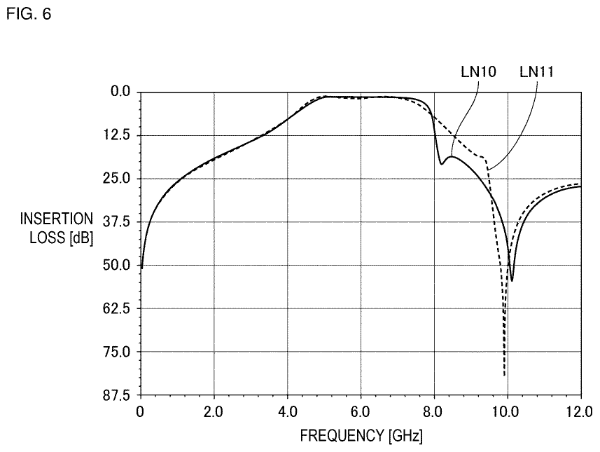

Next, filter characteristics of the filter device 100 of the first example embodiment and a filter device of a comparative example are described with reference to FIGS. 5 and 6.

FIG. 5 is an exploded perspective view of a multilayer structure of a filter device 100X according to a comparative example. The filter device 100X is different from the filter device 100 of the first example embodiment illustrated in FIG. 4 in the layout of electrodes on or in the dielectric layer LY10. Specifically, on or in the dielectric layer LY10 of the filter device 100X, the ground electrodes PG1 and PG2 in the filter device 100 are combined into a ground electrode PG1A. The vias VG2 and VG3 are connected to the ground electrode PG1A. That is, a common ground electrode is used for the resonant circuits RC1 to RC4.

FIG. 6 is a graph for describing filter characteristics of the filter device 100 according to the first example embodiment and the filter device 100X according to the comparative example. In FIG. 6, the horizontal axis indicates a frequency, and the vertical axis indicates insertion loss. In FIG. 6, a solid line LN10 corresponds to the filter device 100 of the first example embodiment, and a dotted line LN11 corresponds to the filter device 100X of the comparative example.

Referring to FIG. 6, in the filter device 100, attenuation poles occur at around 8.5 GHz and 10.2 Hz in a stopband higher than the pass band. In contrast, in the filter device 100X of the comparative example, an attenuation pole occurs only at around 10 GHz. Thus, in the filter device 100, compared to the filter device 100X, the pass band on the high frequency side is wider, and the attenuation near the pass band is steeper.

In the filter device 100X, because a common ground electrode is used, the magnetic coupling between the resonant circuits RC1 and RC3 and the resonant circuits RC2 and RC4 becomes stronger than that in the filter device 100, and the apparent inductance becomes smaller. This is considered to be the cause of the increase in the frequency of the attenuation pole in the filter device 100X, which corresponds to the attenuation pole in the filter device 100 at around 8.5 GHz.

Thus, in a filter device including multiple resonant circuits, it is possible to prevent unintended magnetic coupling, which occurs between the resonant circuits via an electric current flowing through a ground electrode, by providing separate ground electrodes connected to the resonant circuits. This in turn makes it possible to set an attenuation pole at a designed frequency and thereby prevent the degradation of filter characteristics.

Also, in the filter device 100, the vias VG1 to VG3, which are used for grounding and extend from the planar electrode PL20 to the ground electrodes PG1 and PG2, are shared by multiple resonant circuits. This makes it possible to reduce the area occupied by the vias in the dielectric substrate. This in turn makes it possible to reduce the size of a filter device, improve design flexibility, and reduce coupling between vias.

The vias VG2 and VG3 connected to the separate ground electrodes may have different diameters to adjust the degree of coupling. In the filter device 100, the ground electrode PG1 is shared by the resonant circuit RC1 and the resonant circuit RC3, and the ground electrode PG2 is shared by the resonant circuit RC2 and the resonant circuit RC4. However, separate ground electrodes may be provided for the respective resonant circuits.

“Resonant circuits RC1 to RC4” in the first example embodiment correspond, respectively, to “first through fourth resonant circuits” in the present disclosure. “Input terminal T1” and “output terminal T2” in the first example embodiment correspond to “first terminal” and “second terminal” in the present disclosure, respectively. “Ground electrode PG1” and “ground electrode PG2” in the first example embodiment correspond to “first ground electrode” and “second ground electrode” in the present disclosure, respectively. “Via VG2” and “via VG3” in the first example embodiment correspond to “first via” and “second via” in the present disclosure, respectively. “Ground terminal GND1” and “ground terminal GND2” in the first example embodiment correspond to “first ground terminal” and “second ground terminal” in the present disclosure, respectively.

### First Variation

In the configuration of a first variation, the mode of coupling between the resonant circuits RC1 and RC3 and the resonant circuits RC2 and RC4 differs from that in the first example embodiment.

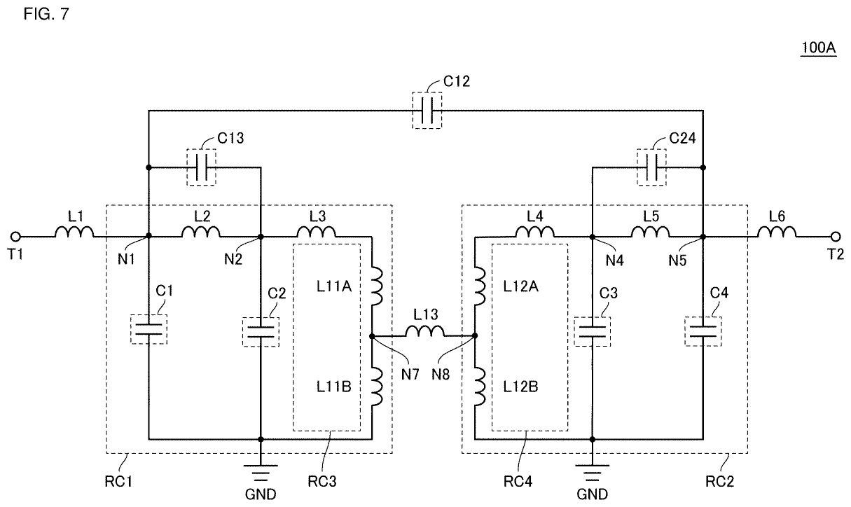

FIG. 7 is an equivalent circuit diagram of a filter device 100A according to the first variation. Compared to the equivalent circuit of the filter device 100 of the first example embodiment illustrated in FIG. 2, the filter device 100A includes inductors L11A, L11B, L12A, L12B, and L13 instead of the inductors L10, L11, and L12. Other components in FIG. 7 are the same as those in FIG. 2, and the descriptions of those components are not repeated.

In the filter device 100A, the inductor L3 and the inductor L4 are separated from each other. The inductors L3, L11A, and L11B are connected in series between the connection node N2 and a ground terminal GND. The inductors L4, L12A, and L12B are connected in series between the connection node N4 and a ground terminal GND.

In the filter device 100A, the resonant circuit RC3 includes the series-connected inductors L3, L11A, and L11B and the capacitor C2 connected in parallel with the inductors L3, L11A, and L11B. Similarly, the resonant circuit RC4 includes the series-connected inductors L4, L12A, and L12B and the capacitor C3 connected in parallel with the inductors L4, L12A, and L12B.

Also, the inductor L13 is connected between a connection node N6 between the inductor L11A and the inductor L11B and a connection node N7 between the inductor L12A and the inductor L12B. In other words, the resonant circuits RC1 and RC3 and the resonant circuits RC2 and RC4 are magnetically coupled via the inductor L13.

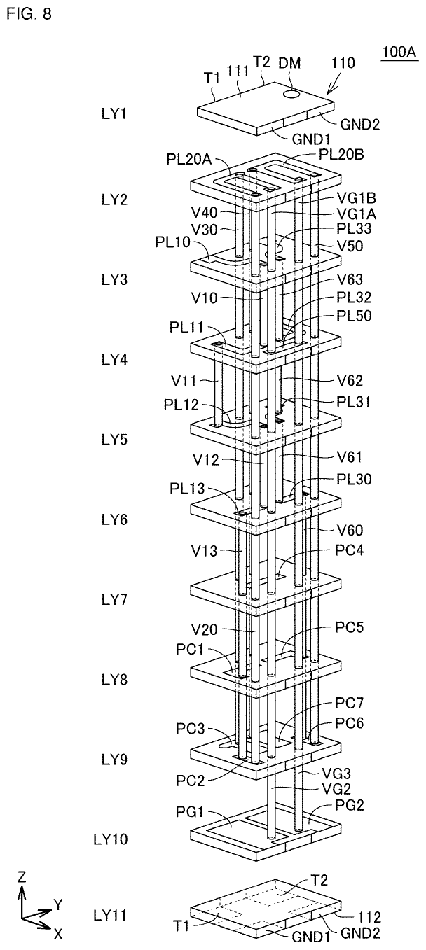

FIG. 8 is an exploded perspective view of an example of a multilayer structure of the filter device 100A according to the first variation. Referring to FIG. 8, the filter device 100A differs from the filter device 100 illustrated in FIG. 4 in that planar electrodes PL20A and PL20B are provided on or in the dielectric layer LY2 instead of the planar electrode PL20, and vias VG1A and VG1B are provided instead of the vias VG1 to VG3. Other components in FIG. 8 are the same as those in FIG. 4, and the descriptions of those components are not repeated.

Each of the planar electrodes PL20A and PL20B is a stripe electrode having a substantially U-shape. The via V20 is connected to a first end of the planar electrode PL20A, and the via VG1A is connected to a second end of the planar electrode PL20A. The via V30 is connected to an intermediate point along the path of the planar electrode PL20A from the via V20 to the via VG1A.

The via V50 is connected to a first end of the planar electrode PL20B, and the via VG1B is connected to a second end of the planar electrode PL20B. The via V40 is connected to an intermediate point along the path of the planar electrode PL20B from the via V50 to the via VG1B.

That is, the planar electrode PL20A is shared by the resonant circuit RC1 and the resonant circuit RC3. Also, the planar electrode PL20B is shared by the resonant circuit RC2 and the resonant circuit RC4.

The via VG1A is connected to the ground electrode PG1 on or in the dielectric layer LY10. The via VG1B is connected to the ground electrode PG2 on or in the dielectric layer LY10. The via VG1A and the via VG1B are connected to each other by the planar electrode PL50 on or in the dielectric layer LY4.

The inductors L11A and L11B in FIG. 7 are implemented by the via VG1A. The inductors L12A and L12B in FIG. 7 are implemented by the via VG1B. Also, the inductor L13 in FIG. 7 includes the planar electrode PL50.

Also in the filter device 100A, the ground electrode PG1 connected to the resonant circuits RC1 and RC3 is separated from the ground electrode PG2 connected to the resonant circuits RC2 and RC4. This makes it possible to prevent unintended magnetic coupling that occurs between resonant circuits via an electric current flowing through a ground electrode. This in turn makes it possible to prevent the degradation of filter characteristics.

In the filter device 100A of the first variation, the resonant circuits RC1 and RC3 are coupled with the resonant circuits RC2 and RC4 via the inductor L13. This configuration makes it possible to easily adjust the coupling between the resonant circuits by adjusting the inductance of the inductor L13.

“Planar electrode PL20A” and “planar electrode PL20B” in the first variation correspond to “first common electrode” and “second common electrode” in the present disclosure, respectively.

### Second Example Embodiment

In the first example embodiment and the first variation, filter devices including four resonant circuits are described. In a second example embodiment and second and third variations of example embodiments of the present invention, configurations of filter devices each including two resonant circuits are described.

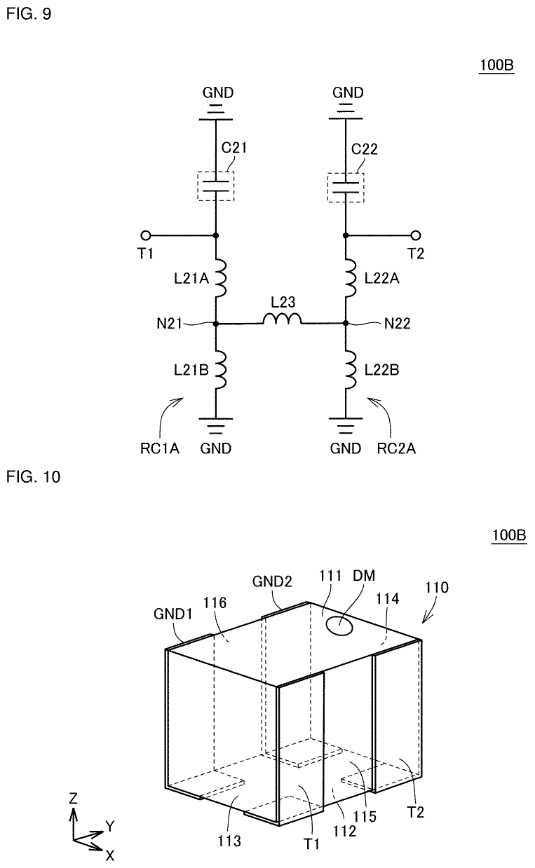

FIG. 9 is an equivalent circuit diagram of a filter device 100B according to the second example embodiment. The filter device 100B includes a resonant circuit RC1A connected to the input terminal T1 and a resonant circuit RC2A connected to the output terminal T2.

The resonant circuit RC1A includes inductors L21A and L21B and a capacitor C21. The resonant circuit RC2A includes inductors L22A and L22B and a capacitor C22.

The capacitor C21 of the resonant circuit RC1A is connected between the input terminal T1 and a ground terminal GND. Also, the inductors L21A and L21B are connected in series between the input terminal T1 and a ground terminal GND. In other words, an LC parallel resonant circuit includes the series-connected inductors L21A and L21B and the capacitor C21 connected in parallel with the inductors L21A and L21B.

Similarly, the capacitor C22 of the resonant circuit RC2A is connected between the output terminal T2 and a ground terminal GND. Also, the inductors L22A and L22B are connected in series between the output terminal T2 and a ground terminal GND. In other words, an LC parallel resonant circuit is constituted by the series-connected inductors L22A and L22B and the capacitor C22 connected in parallel with the inductors L22A and L22B.

Furthermore, an inductor L23 is connected between a connection node N21, which is between the inductor L21A and the inductor L21B, and a connection node N22, which is between the inductor L22A and the inductor L22B.

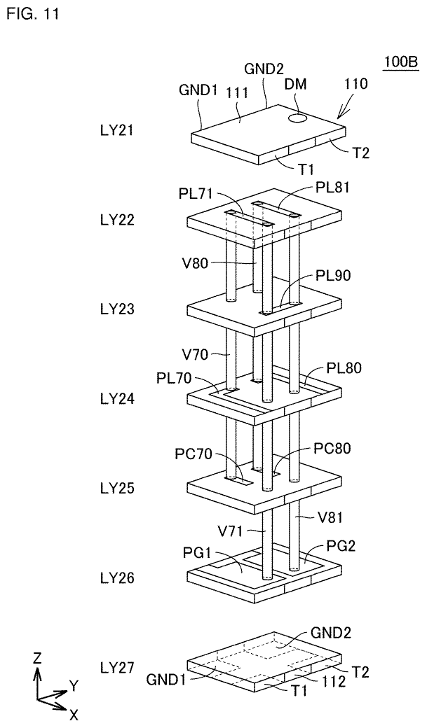

Next, the structure of the filter device 100B is described with reference to FIGS. 10 and 11. FIG. 10 is an external perspective view of the filter device 100B, and FIG. 11 is an exploded perspective view of an example of a multilayer structure of the filter device 100B.

The filter device 100B differs from the filter device 100 of the first example embodiment illustrated in FIG. 3 in the layout of terminals on the outer surface of the dielectric substrate 110. Specifically, as illustrated in FIG. 10, the input terminal T1 and the output terminal T2 extend from the side surface 115 to the lower surface 112 of the dielectric substrate 110, and the ground terminals GND1 and GND2 extend from the side surface 116 to the lower surface 112.

Referring to FIG. 11, the dielectric substrate 110 of the filter device 100B includes dielectric layers LY21 to LY27.

The input terminal T1 is connected, on the side surface 115, to a planar electrode PL70 on or in the dielectric layer LY24. The planar electrode PL70 is a strip electrode having a substantially L-shape, and a first end of the planar electrode PL70 is connected to the input terminal T1 on the side surface 115. A second end of the planar electrode PL70 is connected through a via V70 to a planar electrode PL71 on or in the dielectric layer LY21 and a capacitor electrode PC70 on or in the dielectric layer LY25.

The capacitor electrode PC70 is a planar electrode having a linear shape and extending in the X-axis direction. In plan view from the normal direction of the dielectric substrate 110, at least a portion of the capacitor electrode PC70 overlaps a ground electrode PG1 on or in the dielectric layer LY26. Similarly to the filter device 100 of the first example embodiment, the ground electrode PG1 is a planar electrode having a substantially rectangular shape and is connected to the ground terminal GND1 on the side surface 116. The capacitor C21 in FIG. 9 includes the capacitor electrode PC70 and the ground electrode PG1.

The planar electrode PL71 is a linear electrode extending in the X-axis direction, and a first end of the planar electrode PL71 is connected to the via V70. A second end of the planar electrode PL71 is connected through a via V71 to the ground electrode PG1. The inductors L21A and L21B in FIG. 9 are implemented by the vias V70 and V71 and the planar electrode PL71.

The output terminal T2 is connected, on the side surface 115, to a planar electrode PL80 on or in the dielectric layer LY24. The planar electrode PL80 is a strip electrode having a substantially L-shape that is symmetrical to the planar electrode PL70. A first end of the planar electrode PL80 is connected to the output terminal T2 on the side surface 115. A second end of the planar electrode PL80 is connected through a via V80 to a planar electrode PL81 on or in the dielectric layer LY21 and a capacitor electrode PC80 on or in the dielectric layer LY25.

The capacitor electrode PC80 is a planar electrode having a linear shape and extending in the X-axis direction. In plan view from the normal direction of the dielectric substrate 110, at least a portion of the capacitor electrode PC80 overlaps the ground electrode PG2 on or in the dielectric layer LY26. The ground electrode PG2 is a planar electrode having a substantially rectangular shape that is symmetrical to the ground electrode PG1, and is spaced apart from the ground electrode PG1 in the positive Y-axis direction. The ground electrode PG2 is connected to the ground terminal GND2 on the side surface 116. The capacitor C22 in FIG. 9 includes the capacitor electrode PC80 and the ground electrode PG2.

The planar electrode PL81 is a linear electrode extending in the X-axis direction, and a first end of the planar electrode PL81 is connected to the via V80. A second end of the planar electrode PL81 is connected through a via V81 to the ground electrode PG2. The inductors L22A and L22B in FIG. 9 are implemented by the vias V80 and V81 and the planar electrode PL81.

The via V71 and the via V81 are connected to each other by a planar electrode PL90 on or in the dielectric layer LY23. The planar electrode PL90 is a linear electrode extending in the Y-axis direction. A first end of the planar electrode PL90 is connected to the via V71, and a second end of the planar electrode PL90 is connected to the via V81. The inductor L23 in FIG. 9 includes the planar electrode PL90.

Also in the filter device 100B of the second example embodiment, the two resonant circuits RC1A and RC2A are connected to the different ground electrodes PG1 and PG2 that are separated from each other. This makes it possible to prevent unintended magnetic coupling that occurs between resonant circuits via an electric current flowing through a ground electrode. This in turn makes it possible to reduce the degradation of filter characteristics.

“Resonant circuit RC1A” and “resonant circuit RC2A” in the second example embodiment correspond to “first resonant circuit” and “second resonant circuit” in the present disclosure, respectively.

### Second Variation

In a second variation of an example embodiment of the present disclosure, in addition to the configuration of the filter device of the second example embodiment, a filter device has a configuration in which two resonant circuits are capacitively coupled with each other.

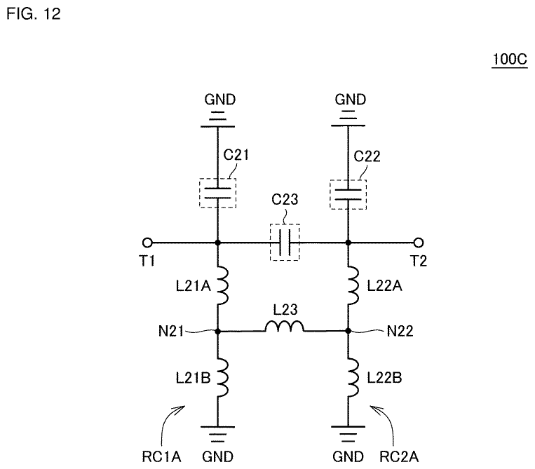

FIG. 12 is an equivalent circuit diagram of a filter device 100C according to the second variation of an example embodiment of the present disclosure. The filter device 100C includes a capacitor C23 in addition to the components of the filter device 100B of the second example embodiment illustrated in FIG. 9. Descriptions of components in FIG. 12, which correspond to those in FIG. 9, are not repeated.

The capacitor C23 is connected between the input terminal T1 and the output terminal T2. With this configuration, the resonant circuit RC1A and the resonant circuit RC2A are magnetically coupled with each other via the inductor L23 and are also capacitively coupled with each other via the capacitor C23. Because the capacitive coupling caused by the capacitor C23 makes it possible to weaken the magnetic coupling caused by the inductor L23, it is possible to adjust the degree of coupling between the resonant circuits by adjusting the capacitance of the capacitor C23.

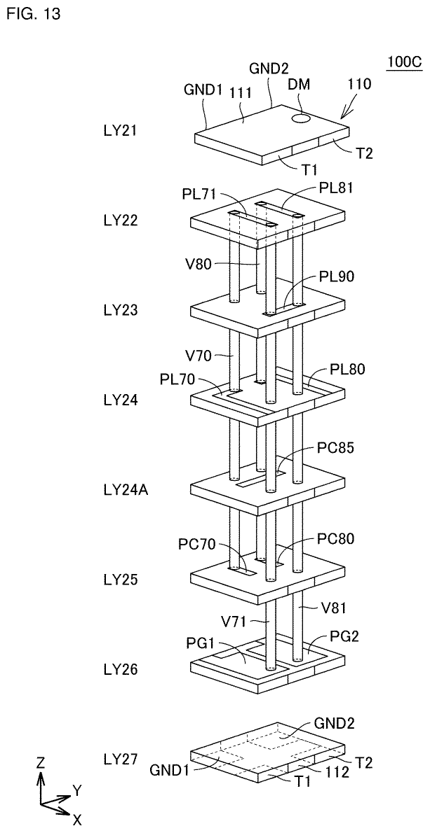

FIG. 13 is an exploded perspective view of an example of a multilayer structure of the filter device 100C according to the second variation. Referring to FIG. 13, the filter device 100C includes, in addition to the components of the filter device 100B illustrated in FIG. 11, a dielectric layer LY24A that is between the dielectric layer LY24 and the dielectric layer LY25. A capacitor electrode PC85 is on or in the dielectric layer LY24A. Descriptions of components in FIG. 13, which correspond to those in FIG. 11, are not repeated.

The capacitor electrode PC85, which is on or in the dielectric layer LY24A, is a planar electrode having a linear shape and extending in the Y-axis direction. In plan view from the normal direction of the dielectric substrate 110, the capacitor electrode PC85 partially overlaps each of the capacitor electrodes PC70 and PC80 on or in the dielectric layer LY25. The capacitor C23 in FIG. 12 includes the capacitor electrodes PC70, PC80, and PC85.

Also in the filter device 100C of the second variation, the two resonant circuits RC1A and RC2A are connected to the different ground electrodes PG1 and PG2 that are separated from each other. This makes it possible to prevent unintended magnetic coupling that occurs between resonant circuits via an electric current flowing through a ground electrode. This in turn makes it possible to reduce the degradation of filter characteristics.

### Third Variation

In the configuration described in a third variation of an example embodiment of the present disclosure, two resonant circuits are capacitively coupled with each other via ground electrodes.

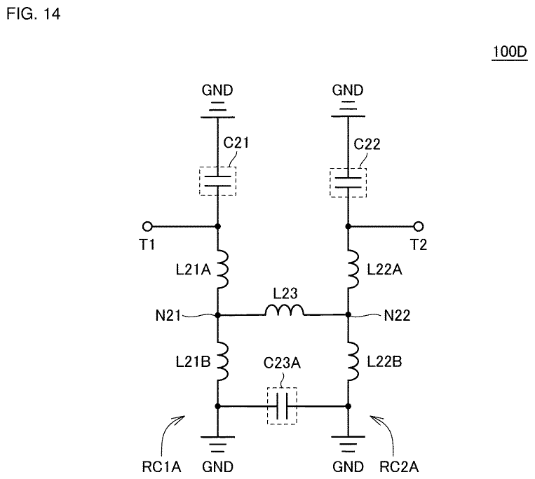

FIG. 14 is an equivalent circuit diagram of a filter device 100D according to the third variation. The filter device 100D includes a capacitor C23A in addition to the components of the filter device 100B of the second example embodiment illustrated in FIG. 9. Descriptions of components in FIG. 14, which correspond to those in FIG. 9, are not repeated.

The capacitor C23A is connected between a ground terminal GND connected to the resonant circuit RC1A and a ground terminal GND connected to the resonant circuit RC2A. The resonant circuit RC1A and the resonant circuit RC2A are magnetically coupled with each other via the inductor L23 and are also capacitively coupled with each other via the capacitor C23A. This makes it possible to adjust the degree of coupling between the resonant circuits by adjusting the capacitance of the capacitor C23A. Furthermore, because the resonant circuits RC1A and RC2A are capacitively coupled with each other via the ground electrodes PG1 and PG2, it is possible to place the capacitor C23A in the same dielectric layer as the capacitors C21 and C22 of the resonant circuits RC1A and RC2A. This makes it possible to reduce the number of layers of the dielectric substrate 110 compared with the filter device 100C of the second variation.

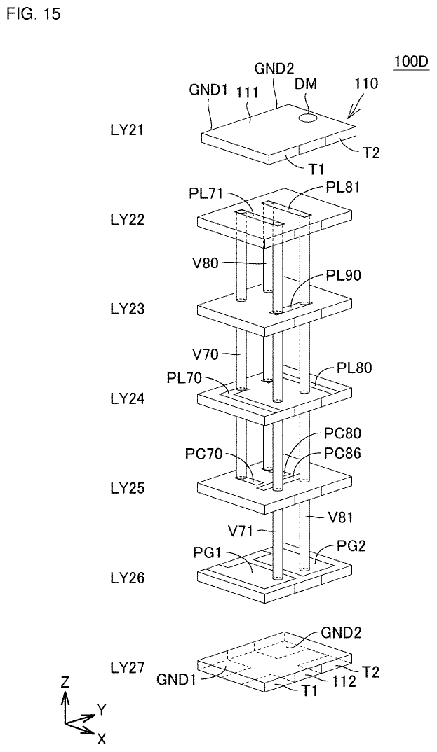

FIG. 15 is an exploded perspective view of an example of a multilayer structure of the filter device 100D according to the third variation. Referring to FIG. 15, the filter device 100D includes a capacitor electrode PC86 on or in the dielectric layer LY25 in addition to the components of the filter device 100B illustrated in FIG. 11. Descriptions of components in FIG. 15, which correspond to those in FIG. 11, are not repeated.

The capacitor electrode PC86 is a planar electrode having a linear shape and extending in the Y-axis direction and is spaced apart from the capacitor electrodes PC70 and PC80 in the positive X-axis direction. In plan view from the normal direction of the dielectric substrate 110, the capacitor electrode PC86 partially overlaps the ground electrodes PG1 and PG2 on or in the dielectric layer LY26. The capacitor C23A in FIG. 14 includes the capacitor electrode PC86 and the ground electrodes PG1 and PG2.

Also in the filter device 100D of the third variation, the two resonant circuits RC1A and RC2A are connected to the different ground electrodes PG1 and PG2 that are separated from each other. This makes it possible to prevent unintended magnetic coupling that occurs between resonant circuits via an electric current flowing through a ground electrode. This in turn makes it possible to reduce the degradation of filter characteristics.

While example embodiments of the present invention have been described above, it is to be understood that variations and modifications will be apparent to those skilled in the art without departing from the scope and spirit of the present invention. The scope of the present invention, therefore, is to be determined solely by the following claims.

What is claimed is:

1. A filter device comprising:
a dielectric substrate;
a first terminal and a second terminal on an outer surface of the dielectric substrate;
a first resonant circuit connected to the first terminal;
a second resonant circuit connected to the second terminal;
a first ground electrode connected to the first resonant circuit; and
a second ground electrode connected to the second resonant circuit and separated from the first ground electrode.

2. The filter device according to claim 1, wherein each of the first resonant circuit and the second resonant circuit is an LC resonant circuit including inductors and a capacitor.

3. The filter device according to claim 2, wherein the first resonant circuit and the second resonant circuit share one or more of the inductors.

4. The filter device according to claim 1, wherein the first resonant circuit is capacitively coupled with the second resonant circuit.

5. The filter device according to claim 1, wherein
the first resonant circuit includes a first via connected to the first ground electrode;
the second resonant circuit includes a second via connected to the second ground electrode; and
the first via is connected to the second via.

6. The filter device according to claim 1, further comprising:
a capacitor electrode that partially overlaps both the first ground electrode and the second ground electrode in plan view from a normal direction of the dielectric substrate.

7. The filter device according to claim 5, further comprising:
a first ground terminal and a second ground terminal on the outer surface of the dielectric substrate; wherein
the first ground electrode and the second ground electrode are on or in an inner layer of the dielectric substrate;
the first ground electrode is connected to the first ground terminal; and
the second ground electrode is connected to the second ground terminal.

8. The filter device according to claim 1, further comprising:
a third resonant circuit electromagnetically coupled with the first resonant circuit; and
a fourth resonant circuit electromagnetically coupled with the second resonant circuit.

9. The filter device according to claim 8, further comprising:
a common electrode connected to the first resonant circuit, the second resonant circuit, the third resonant circuit, and the fourth resonant circuit.

10. The filter device according to claim 8, further comprising:
a first common electrode connected to the first resonant circuit and the third resonant circuit; and
a second common electrode connected to the second resonant circuit and the fourth resonant circuit.

11. The filter device according to claim 8, wherein each of the first resonant circuit, the second resonant circuit, the third resonant circuit, and the fourth resonant circuit is an LC resonant circuit including inductors and a capacitor.

12. The filter device according to claim 11, wherein
the first resonant circuit and the third resonant circuit share one or more of the inductors; and
the second resonant circuit and the fourth resonant circuit share one or more of the inductors.

13. The filter device according to claim 11, wherein the first resonant circuit, the second resonant circuit, the third resonant circuit, and the fourth resonant circuit share one or more of the inductors.

14. A radio-frequency front-end circuit comprising the filter device according to claim 1.

15. The radio-frequency front-end circuit according to claim 14, wherein each of the first resonant circuit and the second resonant circuit is an LC resonant circuit including inductors and a capacitor.

16. The radio-frequency front-end circuit according to claim 15, wherein the first resonant circuit and the second resonant circuit share one or more of the inductors.

17. The radio-frequency front-end circuit according to claim 14, wherein the first resonant circuit is capacitively coupled with the second resonant circuit.

18. The radio-frequency front-end circuit according to claim 14, wherein
the first resonant circuit includes a first via connected to the first ground electrode;
the second resonant circuit includes a second via connected to the second ground electrode; and
the first via is connected to the second via.

19. The radio-frequency front-end circuit according to claim 14, further comprising:
a capacitor electrode that partially overlaps both the first ground electrode and the second ground electrode in plan view from a normal direction of the dielectric substrate.

20. The radio-frequency front-end circuit according to claim 18, further comprising:
a first ground terminal and a second ground terminal on the outer surface of the dielectric substrate; wherein
the first ground electrode and the second ground electrode are on or in an inner layer of the dielectric substrate;
the first ground electrode is connected to the first ground terminal; and
the second ground electrode is connected to the second ground terminal.
